(19) United States
(12) Patent Application Publication
(10) Pub. No.: US 2009/0212282 A1
(43) Pub. Date: Aug. 27, 2009

(54) Bright visible wavelength luminescent nanostructures and methods of making and devices for using the same

(75) Inventors: Jie Lui, Durham, NC (US); Jianye Li, Evanston, IL (US); Henry O. Everitt, Durham, NC (US); Hongying Peng, Durham, NC (US); John V. Foreman, Durham, NC (US)

Correspondence Address: NIXON & VANDERHYE, PC, 901 NORTH GLEBE ROAD, 11TH FLOOR, ARLINGTON, VA, 22203, US

(73) Assignee: DUKE UNIVERSITY, Durham, NC (US)

(21) Appl. No.: 11/918,442

(22) PCT Filed: Apr. 13, 2006
(86) PCT No.: PCT/US2006/013855

§ 371 Date: Apr. 10, 2009

Related U.S. Application Data
(60) Provisional application No. 60/671,210, filed on Apr. 14, 2005.

(51) Int. Cl. H01L 33/00; C09K 11/54; C09K 11/56

(52) U.S. Cl. 257/43; 252/301.6 R; 252/301.6 S; 977/811; 977/950; 257/E33.019

(57) ABSTRACT

Luminescent nanostructures (e.g., nanowires) and devices are provided which are capable of emitting bright visible light. The luminescent nanowires are most preferably in the form of a doped ZnO having a spectrally integrated ratio of visible to UV light of at least about 1000 or greater. The dopant for the ZnO luminescent nanowires may be at least one of sulfur, selenium, oxygen, zinc, magnesium, aluminum, with sulfur being especially preferred. The doped ZnO luminescent nanowires may be provided in devices for emitting visible light whereby visible light is emitted by the doped ZnO luminescent nanowires in response to excitation by UV light provided by a UV light source. The device may preferably comprise a transparent or translucent lens covering the UV light source, wherein the doped ZnO luminescent nanowires are present as a coating on a surface of the lens. In some embodiments, the device will comprise multiple UV light sources. Devices of the present invention may be provided with a flat panel lens which is positioned adjacent the multiple UV light sources and has a coating of the doped ZnO luminescent nanowires thereon.

### CROSS-REFERENCE TO RELATED APPLICATION

The present application is based on and claims domestic priority benefits under 35 USC §119(e) from U.S. Provisional Application Ser. No. 60/671,210 filed on Apr. 14, 2005, the entire content of which is expressly incorporated hereinto by reference.

### GOVERNMENT RIGHTS STATEMENT

This invention was made with Government support under Grant No. W011NF-04-D-001/DI#002 awarded by the Army Research Office and Grant No. 49620-02-1-0188 awarded by the Air Force Office of Scientific Research. The Government has certain rights in the invention.

### FIELD OF THE INVENTION

The present invention relates generally to visible light generation. In preferred forms, the present invention relates to visible light generation by means of doped zinc oxide materials in the form of nanowires.

### BACKGROUND AND SUMMARY OF THE INVENTION

Increasing interest in the optoelectronic properties of wide band gap semiconductor materials, heterostructures, and nanostructures is largely motivated by the need to develop bright emitters and phosphors in the ultraviolet and visible wavelength regions. In spite of the commercial success of the III-V gallium nitride (GaN) material system, interest in the II-VI semiconductor zinc oxide (ZnO) was renewed in the late 1990s when room-temperature, optically pumped lasing was demonstrated for ZnO thin films.¹⁻⁵ Since that time the optical properties of ZnO bulk single crystal, thin films, and nanostructures have been studied extensively. Frequently cited advantages of ZnO over GaN include a larger exciton binding energy^{6,7} (60 meV vs. 26 meV), the availability of high-quality single-crystal ZnO substrates, amenability to chemical etching, resistance to oxidation, environmental friendliness, and lower cost. Progress is even being made toward establishing reproducible methods for p-doping ZnO.⁸⁻¹²

The other outstanding issue related to optoelectronic applications of ZnO is improved material quality, often characterized by the degree of broad, defect-related “green band” or “visible band” emission (centered at ˜2.5 eV) that almost always accompanies the ultraviolet (UV) band edge emission (˜3.3 eV at 295 K). In bulk ZnO and in thin films of sufficient quality, the intensity of visible emission is several orders of magnitude weaker than that of the band edge emission.¹³⁻¹⁶ For ZnO nanostructures, however, the intensity of the defect emission can be much stronger. Indeed, the peak intensity ratio (≡I_{D}^{Peak}/I_{B}^{Peak}) of the defect emission to the band edge emission has been reported as large as 10, but because the visible emission is broader, the spectrally integrated ratio (≡I_{D}/I_{B}) is as large as 40.¹⁷⁻²⁰ Furthermore, it is well established that sulfur doping enhances the visible emission from ZnO nanowires, with I_{D}/I_{B}≦22 at room temperature^{21,22} and I_{D}/I_{B˜1500} at 10 K.²³ In these reports it has been suggested that sulfur substitutes for oxygen within the ZnO lattice, and the enhanced visible emission is due to the commensurate increase in oxygen vacancies.

The chemical and structural origins of the visible luminescence from undoped ZnO are still a matter of debate. In what is perhaps the most frequently cited explanation,²⁴ electrons trapped at singly ionized oxygen vacancies recombine with valence band holes. In another frequently cited explanation,²⁵ electrons in the conduction band and/or shallow donor states recombine with holes which have been trapped at oxygen vacancies. The significant contribution of surface defects to visible emission is evident from the observation that I_{D}^{Peak}/I_{B}^{Peak} is much higher in ZnO nanostructures than in bulk or thin films due to the nanostructures' increased surface-to-volume ratio. Indeed, recent work by Shalish et al. demonstrated that the intensity of defect emission in an array of ZnO nanowires was directly proportional to the wires' average surface-to-volume ratio.²⁰ Measurements of the polarization of band edge versus defect emission¹⁸ and studies involving surfactant treatments in ZnO nanostructures^{26,27} also indicate that the visible emission originates from the surfaces of these materials, thus lending further support to the claim that surface defects are primarily responsible for the visible emission.

It would be highly beneficial if doped ZnO nanostructures could be employed as a possible UV-excited phosphor producing bright, efficient, and broad visible-wavelength light. It is towards providing such a need that the present invention is directed.

Broadly, the present invention is directed toward doped ZnO nanostructures (e.g., nanowires) which produce bright, efficient, and broad visible-wavelength light when excited. In especially preferred forms, the present invention is embodied in sulfur-doped ZnO nanowires whose integrated visible emission is broad and more than three orders of magnitude brighter than the band edge UV emission. In contrast to previous reports of greater visible emission with increasing surface-to-volume ratio in ZnO, the present applicants have discovered that nanostructuring sulfur-doped ZnO introduces nonradiative relaxation pathways that reduce the visible luminescence efficiency.

Embodiments according to the invention include devices, systems and methods for using doped ZnO luminescent nanostructures for visible light emissions. In certain embodiments, nanowires, such as doped ZnO nanowires, are used as phosphors to coat a light emitting diode (LED). In some embodiments, the p-type and/or n-type material of an LED is formed using p-type and/or n-type nanowires, such as ZnO nanowires. In particular embodiments, an LED includes an n-type material formed of n-doped ZnO nanowires and a p-type material formed of another material, such as p-type GaN. In some embodiments, nanowires having different light emissions may be combined to provide a broad light emissions spectrum.

According to embodiments of the invention, nanowires are used for white light generation. In particular embodiments, ZnO nanowires, which can be produced to emit strong and broad visible light, are used for white light generation. Such materials can be used as phosphor as well as the light-emitting component in light emitting diode devices. Applications for the light emitting devices include light bulbs for general use, display backlighting, large area illumination, traffic lights, headlights for automobiles, trains, ships and planes, flashlight etc.

In embodiments of the present invention, luminescent nanowires are provided which are capable of emitting bright visible light, the luminescent nanostructures being comprised of a doped ZnO having a spectrally integrated ratio of at least about 200 or greater. Preferably, the doped ZnO luminescent nanostructures are in the form of nanowires. The doped ZnO luminescent nanostructures may be comprised of ZnO which is doped with at least one dopant selected from the group consisting of sulfur, selenium, oxygen, zinc, magnesium, aluminum. Sulfur is especially preferred. The doped ZnO luminescent materials of the present invention will most preferably exhibit a spectrally integrated ratio of visible to UV emission of at least about 1000.

Nanowires formed in accordance with the present invention will have a length of up to about 100 μm and an average diameter of between about 100 nm to about 900 nm.

In accordance with other aspects of the invention, a process for fabricating sulfur-doped ZnO luminescent nanowires is provided which comprises forming a source material by mixing ZnS and graphite powder, and heating the source material in the presence of oxygen for a time sufficient to grow sulfur-doped ZnO nanowires.

In yet another aspect of the present invention, devices for emitting visible light are provided which comprise a doped ZnO luminescent nanostructures and a UV light source, the doped ZnO nanostructures emitting visible light in response to excitation by UV light emitted by the UV light source. The device may preferably comprise a transparent or translucent lens covering the UV light source, wherein the doped ZnO luminescent material is present as a coating on a surface of the lens. The coating of the doped ZnO luminescent nanostructures may be in the form of nanowires. In some embodiments, the device will comprise multiple UV light sources. Devices of the present invention may be provided with a flat panel lens which is positioned adjacent the multiple UV light sources.

These and other aspects and advantages will become more apparent after careful consideration is given to the following detailed description of the preferred exemplary embodiments thereof.

### BRIEF DESCRIPTION OF THE ACCOMPANYING DRAWINGS

Reference will hereinafter be made to the accompanying drawings, wherein like reference numerals throughout the various FIGURES denote like structural elements, and wherein;

FIG. 1 is a schematic illustration of one embodiment of a visible white light emitting device in accordance with the present invention;

FIG. 2 is a schematic illustration of another embodiment of a visible white light emitting device in accordance with the present invention;

FIGS. 3A to 3D depict a fabrication technique in accordance with the present invention by which nanowire LEDs may be fabricated directly using ZnO nanowires;

FIG. 4 is a is an X-ray diffraction (XRD) plot for one of the doped ZnO nanowire samples produced in the Examples below;

FIG. 5 is a composite scanning electron microscope (SEM) photograph at different magnifications of the doped ZnO nanowire samples produced in the Examples below;

FIG. 6 are photoluminescence (PL) spectra of doped ZnO nanowires, and doped and undoped micropowders in comparison to the dark-adapted human eye²⁸, with all spectra having been corrected for the samples' respective absorption;

FIG. 7 are PL excitation spectra of the sulfur doped nanowires and micropowders of the present invention for a detection energy of 2.5 eV and with all spectra normalized to the excitonic resonance at 3.30 eV;

FIG. 8 are time-resolved, spectrally-integrated band edge photoluminescence spectra of ZnO micropowders and nanowires; and

FIG. 9 is a time-resolved, spectrally-integrated PL spectra from sulfur-doped ZnO micropowder and nanowires which show the complex and slow decay of visible wavelength emission;

### DETAILED DESCRIPTION OF THE INVENTION

### A. Definitions

The following terms used throughout the specification and/or claims are intended to have the definitional meanings as set forth below.

“Nanowire” is meant to refer to continuous wire or filament of indefinite length having an average effective diameter of nanometer (nm) dimensions. The term nanowires is therefore intended to refer to nanostructures of indefinite length having a generally circular cross-sectional configuration as well as other nanostructures of indefinite length with non-circular cross-sections such as nanobelts having a generally rectangular cross-section.

“Micropowder” is meant to refer to particulate material having an average effective diameter of micrometer (μm) dimensions.

“Average effective diameter” is meant to refer to the average of the smallest circle which entirely encompasses a cross-section of a nanowire.

“Ultra-violet” sometimes abbreviated as “UV” is meant to refer to light having a wavelength of 360 nm up to and including 410 nm;

“Visible” is meant to refer to light having a wavelength of greater than 410 nm up to and including 700 nm.

“Spectrally integrated ratio” sometimes abbreviated as “SIR” is the ratio of visible to UV light, or more particularly the ratio of the defect emission (I_{D}) to the ultraviolet band edge emission (I_{B}) represented by I_{D}/I_{B}.

It will also be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of “over” and “under”. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

### B. Description of the Preferred Embodiments

The visible light luminescent nanostructures of the present invention will necessarily consist essentially of doped ZnO. Suitable dopants may include virtually any dopant which increases the spectrally integrated ratio (SIR) of ZnO to at least about 200 or greater, more preferably at least about 300 or greater, and most preferably at least about 1000 or greater. For example, when in the form of nanowires, the doped ZnO luminescent nanostructures will typically exhibit a SIR of 1000 or greater, and usually at least about 1,500 or greater. Suitable dopants include sulfur, selenium, oxygen, zinc, magnesium, aluminum and the like. Sulfur is preferred as the dopant in accordance with the present invention.

In accordance with the present invention nanowires will have indefinite lengths. More specifically, the nanowires of this invention will typically have lengths of up to 100 μm, for example, between about 1 to about 100 μm (preferably between about 10 to 40 μm). The average diameters of the generally circular cross-sectional nanowires will typically range from between 10 to about 990 nm, typically between about 10 to about 750 nm. When in the form of nanobelts, the cross-sectional configuration may be somewhat rectangular with cross-sectional widthwise dimensions ranging from between about 10 to about 990 nm (usually between about 50 to about 750 nm) and cross-sectional thickness dimensions ranging from between about 10 to about 500 nm, usually between about 10 to about 250 nm.

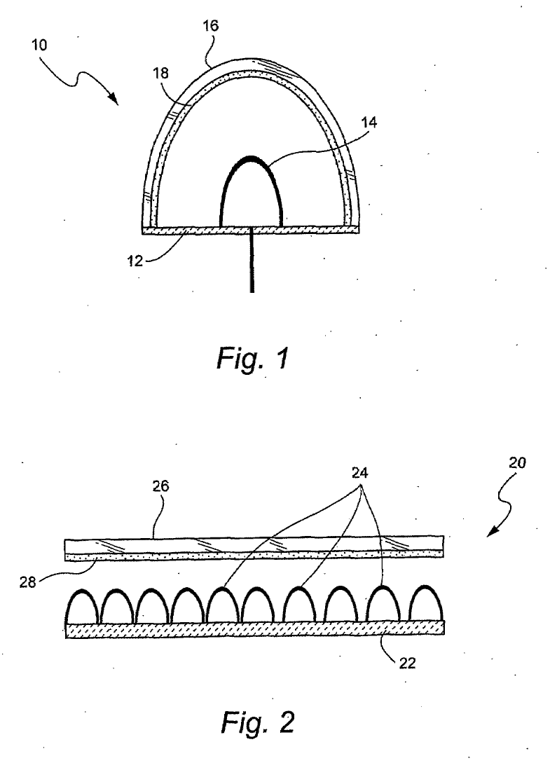

Accompanying FIG. 1 depicts one possible white light emitting device 10 in accordance with the present invention. In this regard, the device 10 depicted in accompanying FIG. 1 is embodied in a single white light emitting structure comprised of a base 12 which supports a conventional UV light emitting diode (UV LED) 14 and a light transparent or translucent lens 16 covering the UV LED 14. A coating 18 of doped ZnO nanowires in accordance with the present invention is on an interior surface of the lens 16. The UV LED 14 is connected to a power source (not shown) so that, when energized, the UV light emitted thereby is directed toward the doped ZnO nanowires coating 18 to excite the same. Upon excitation by the UV light emitted by the UV LED 14, the doped ZnO coating will in turn emit a visible white light.

FIG. 2 depicts a flat panel light device 20 comprised of a base 22 which supports multiple UV LED's 24. A transparent or translucent cover plate 26 is positioned over the UV LED's 24. The interior surface of the cover plate 26 (e.g., the surface of the cover plate 26 which is immediately adjacent to the UV LED's 24) is provided with a coating 28 of a doped ZnO nanowires. Upon energization of the UV LED's 24, the UV light emitted thereby will excite the coating 28 of doped ZnO material which in turn causes it to emit a visible white light.

According to further embodiments of the present invention, white light may be generated by the fabrication of nanowire LEDs directly using ZnO nanowires. This approach may avoid the extra step of using another LED as an excitation source to further reduce the cost and increase the energy efficiency of the light sources. To form an LED, both holes and electrons may be injected into the material for light generation. Thus, controlled doping of the materials may be performed. Normally ZnO nanowires are n doped; however p doped ZnO materials may also be prepared. A pure ZnO LED may be made by using a homojunction of p type and n type ZnO. However, heterojunctions between n type ZnO and p type other materials such as GaAIN can also be made.

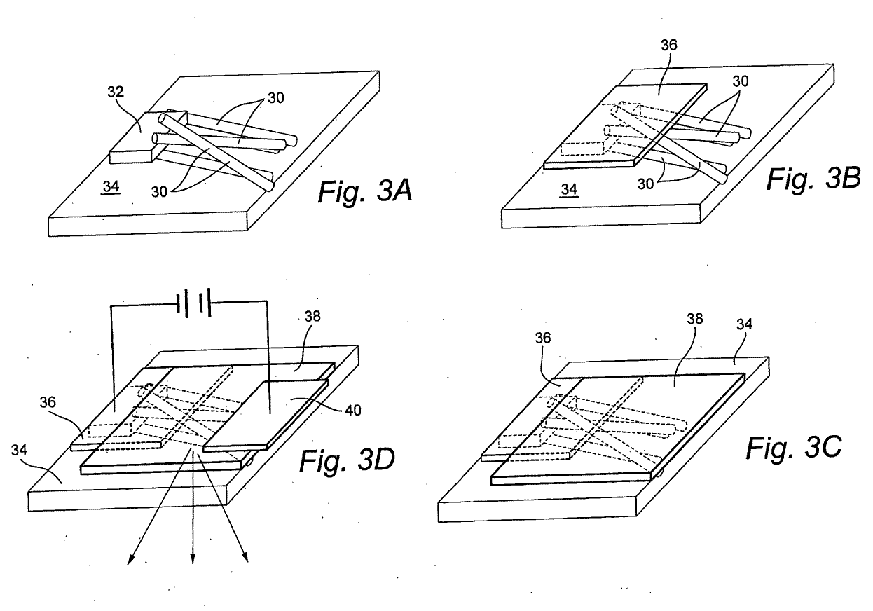

One possible technique to fabricate nanowire LEDs directly using ZnO nanowires is depicted schematically in FIGS. 3A to 3D. In this regard, nanowire LEDs 30 formed of ZnO can be first grown on Au electrodes 32 deposited on transparent quartz glass substrates 34 as shown in FIG. 3A. Photolithogrphy and or shadow masking can be used to evaporate a dielectric materials layer 36 such as SiO₂ to cover the Au electrodes and part of ZnO nanowires (see FIG. 3B). As depicted in FIG. 3C, a GaN can then be grown on the surface to form a thin film 38. A counter electrode 40 can then be evaporated on the GaN materials. The junction between the GaN thin film 38 and ZnO nanowires 30 can serve as the junction where the electron and hole recombine. When such a junction formed, as shown in FIG. 3D, the emission may be mainly from the ZnO region, and thus the emission spectrum of light (shown by the arrows in FIG. 3D) may be determined by the properties of the ZnO materials.

Alternatively, ZnO nanowires can be grown on to existing ZnO nanowires using various methods according to embodiments of the present invention. The ZnO nanowires may emit broad yellow light, which could combine with the broad green emission from the CVD ZNO nanowire to form a even broader emission spectrum. The yellow emission may be from the oxygen interstitial sites in the materials, which implies that the nanowires may be p doped. A p-n junction can be formed between these two different types of ZnO nanowires. Using the same approach as described previously in connection with FIGS. 3A-3D, homojunction ZnO LEDs can be fabricated.

ZnO nanowires in accordance with the present invention may be grown using conventional processing technologies. In this regard, ZnO nanowires may advantageously be grown in a horizontal fused quartz tube inside a tube furnace. The raw materials is most preferably a mixture of ZnS and graphite carbon powder. Catalyst for the growth include Au and Ni film (or particles). Typically, the raw materials may be located at the center (highest temperature zone, 800˜100° C.) of the tube furnace, with the catalyst(s) being placed downstream. Nanowire growth is advantageously carried out under a steady flow of argon of about 50˜500 standard cubic centimeters per minute for 4˜6 hours. During the growth process, trace amount of oxygen in Ar provided an oxygen source in the to convert the ZnS precursor to ZnO.

The present invention will be further understood from the following non-limiting Examples.

### EXAMPLES

### 1. Sample Preparation and Testing Description

In the following Examples, a system was used to grow sulfur-doped ZnO nanowires which was similar to a system that was previously designed to prepare GaN nanowires. See in this regard, Li et al, Chem. Mater. 2004, 16, 1633-1636 (the entire content thereof being expressly incorporated hereinto by reference). Growth was carried out in a horizontal fused quartz tube inside a tube furnace. A mixture of ZnS (99.99%, Alfa Aesar) and graphite carbon powders (99.9995%, Alfa Aesar) with a weight ratio of 2:1 was the source material. The graphite carbon powder was used to lower the growth temperature by decreasing the vaporizing temperature of the source material. The substrates used to deposit the ZnO nanowires were silicon wafers (Silicon Quest) patterned with gold films. The gold patterns were generated by standard photolithography and thermal evaporation.

The source material and the gold-coated substrates were loaded into an alumina boat, and the boat was placed with the source material at the center of the horizontal fused quartz tube. The furnace was then heated under a steady flow of argon (99.99%, National Specialty Gases). When the furnace temperature reached 900° C., the temperature was kept constant for ˜8 hours. The furnace was then switched off and allowed to cool to room temperature. Wool-like products were found on the substrates. During the growth process, the tube was not sealed tightly so that air (oxygen) could enter the tube to oxidize ZnS into ZnO.

To prepare S-doped ZnO powder, a small amount of commercial ZnO powder (typically 300 mg) was heated along with a small amount of S powder (˜10 mg) in a sealed quartz tube at 1000° C. for one hour.

Continuous wave photoluminescence (PL) spectroscopy was performed by photoexciting the samples with a HeCd laser operating at 3.81 eV (325 nm) and focused to an intensity of 0.2 W/cm². The PL was collected and refocused into an all-silica optical fiber using a complementary pair of aluminum off-axis parabolic mirrors. The collected PL was dispersed by a 30-cm imaging spectrometer and measured using a liquid nitrogen-cooled CCD camera. Time resolved photoluminescence (TRPL) spectroscopy was performed by photoexciting the samples with ˜100 fs pulses from a 1 kHz, wavelength-tunable optical parametric amplifier (Quantronix) tuned to 3.81 eV and by routing the collected PL to a Hamamatsu streak camera (30 ps resolution). The excitation energy density was ˜250 μJ/cm². Photoluminescence excitation (PLE) spectroscopy was performed by exciting the samples with the monochromatized output of a 300 W xenon arc lamp. The collected PL was measured using the collection/detection system described above.

Because the band edge and defect emission bands span a large spectral range, the PL was collected and focused into the detector using non-dispersive optics. All measured spectra were corrected for the spectral response of the fiber/spectrometer/CCD system. The PL intensity at wavelength A was scaled by a factor (1/λ²) when plotting PL intensity versus photon energy. Finally, quantum efficiency measurements were performed by exciting the samples with the HeCd laser and using a 4-inch diameter integrating sphere (Labsphere) to collect the PL, following the procedure outlined in de Mello et al, Adv. Mater., 1997, 9, 230-232 (the entire content of which is expressly incorporated hereinto by reference.)

ZnO:S nanowires were grown on gold-coated silicon substrates inside a horizontal tube furnace as described above. Zinc sulfide (ZnS) and carbon (C) were used in a weight ratio of 2:1 as starting materials. Due to trace amounts of oxygen in the argon carrier gas, the zinc is oxidized and S-doped ZnO nanowires were formed.

### 2. Results and Analyses

To ascertain the relative effects of doping and nanostructuring on the optical properties of the nanowires, the emission of the nanowires to that of micrometer-scale ZnO powder in both undoped and sulfur-doped forms were compared. Commercially available, undoped micropowder was obtained from Aldrich®, and a portion of this micropowder was sealed with small amount of sulfur in a quartz tube and annealed at 1000° C. for one hour to produce ZnO:S micropowder.

The optical properties of the samples were characterized using standard spectroscopic equipment in the manner described previously. A HeCd laser operating at 3.81 eV (325 nm) was used for continuous-wave excitation, and the 100 fs pulsed output of a 1 kHz optical parametric amplifier, tuned to the same energy, was used for pulsed excitation during the time-resolved measurements.

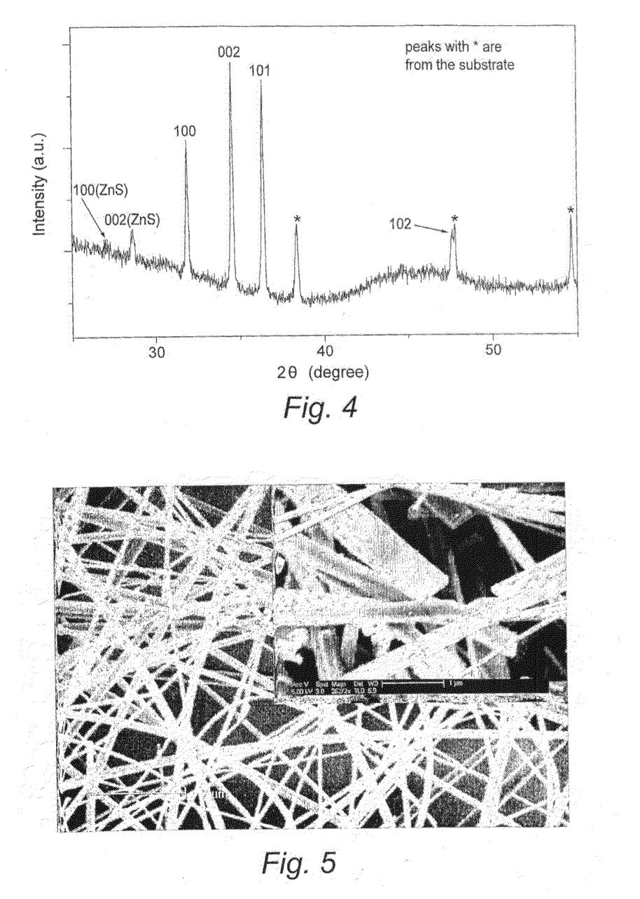

FIGS. 4 and 5 respectively show X-ray diffraction (XRD) and scanning electron microscope (SEM) data for one of the nanowire samples. The strong diffraction peaks in FIG. 4 correspond to ZnO. Two small peaks corresponding to ZnS are also observed, indicating the existence of a small amount of ZnS impurity in the material. The SEM images in FIG. 5 indicate that the nanowires are relatively long (˜20 μm) and uniform along their length, with average cross sections of ˜500×150 nm². SEM data (not shown) for the micropowder samples indicated that the average particle diameter is ˜125 μm

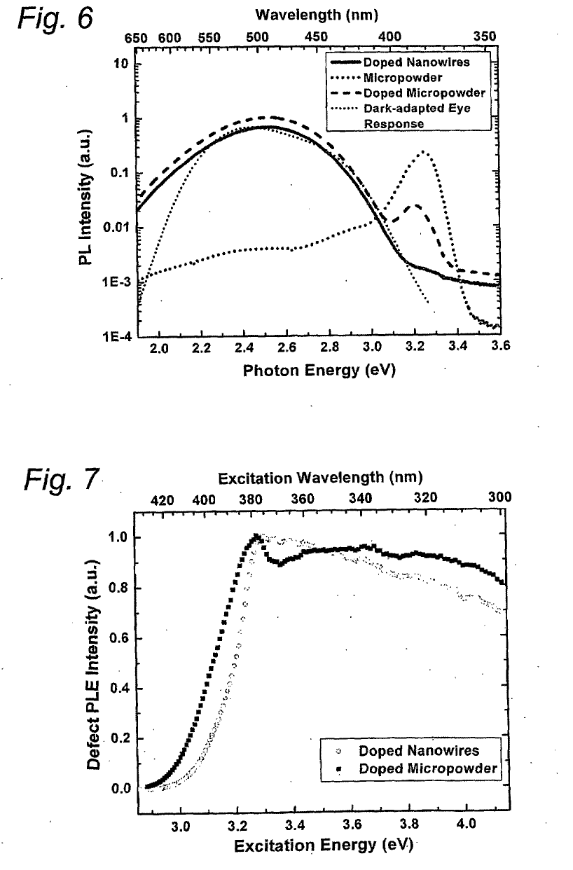

The room temperature, continuous-wave photoluminescence (PL) spectra of spontaneous emission from the sulfur-doped ZnO nanowires, the commercially available undoped ZnO micropowder, and a sulfur-doped portion of the micropowder are shown in FIG. 6. The broad emission spectra of the sulfur-doped ZnO nanowires and micropowders very closely match the dark-adapted response²⁸ of the human eye. Moreover, their brightness and large spectrally integrated quantum efficiencies (30% and 65%, respectively) make them compelling UV-excited excited phosphors. There have been no prior measurements of the quantum efficiency of defect emission from ZnO nanostructures, although a band edge quantum efficiency of approximately 10% has recently been reported for spontaneous emission of undoped ZnO nanowires.²⁹ The 65% quantum efficiency of the S-doped ZnO powder is consistent with a previously reported value of 60%.³⁰

To ascertain what wavelength of UV excitation most efficiently produces the green emission, photoluminescence excitation (PLE) spectroscopy was performed on the doped nanowire and micropowder samples (FIG. 7). An excitonic resonance is clearly observed at 3.30 eV in the absorption profiles, indicating that excitation at the free exciton ground state energy maximizes the intensity of defect emission.

In general, the ratio of defect to band edge emission, I_{D}/I_{B}, depends on growth technique and can be increased through nanostructuring. However, the unprecedented I_{D}^{Peak}/I_{B}^{Peak} of the doped nanowires according to the present invention cannot be explained by nanostructuring alone. The analysis of Shalish et al. regarding undoped ZnO nanowires²⁰ predicts I_{D}^{Peak}/I_{B}^{Peak}=0.3 for an undoped version of the nanowires, not the I_{D}^{Peak}/I_{B}^{Peak}=400 which was observed. Without wishing to be bound to any particular theory, we attribute the factor of about 1300 difference in these ratios to the sulfur doping. In support of this theory it will be noted that I_{D}^{Peak}/I_{B}^{Peak} changes from 0.02 to 80 when comparing undoped to sulfur-doped micropowders—a factor of 4000 change. The similarity in intensity and spectral distribution of the entire broadband emission of the doped nanowires and micropowder (FIG. 2A) suggests a common origin that is lacking for the undoped sample.

As noted above, there is experimental evidence that the visible emission originates from surface states in both undoped^{18,20,26,27} and sulfur-doped²¹ ZnO. It is therefore an unexpected discovery that the sulfur-doped micropowders with small surface-to-volume ratio exhibit double the quantum efficiency and triple the improvement in I_{D}^{Peak}/I_{B}^{Peak} compared to the sulfur-doped nanowires with larger surface-to-volume ratio. Again without wishing to be bound to a particular theory, it can be posited that the greater surface-to-volume ratio in the sulfur-doped nanowires contributes a greater density of nonradiative traps that directly compete with the sulfur-mediated radiative relaxation.

TABLE 1
TRPL biexponential decay characteristics of band edge emission
for undoped and S-doped ZnO micropowders and nanowires.

| | | UV decay | UV decay | UV decay | quantum |
|---|---|---|---|---|---|
| | I_{D}/I_{B} | τ₁ (ns) | T₂ (ns) | A₁ | efficiency |
| Undoped | 0.08 | 0.198 | 1.08 | 0.48 | 7% |
| micropowder | | | | | |
| S-doped | 320 | 0.112 | 0.481 | 0.37 | 65% |
| micropowder | | | | | |
| S-doped | 1600 | <0.040 | — | — | 30% |
| nanowire | | | | | |

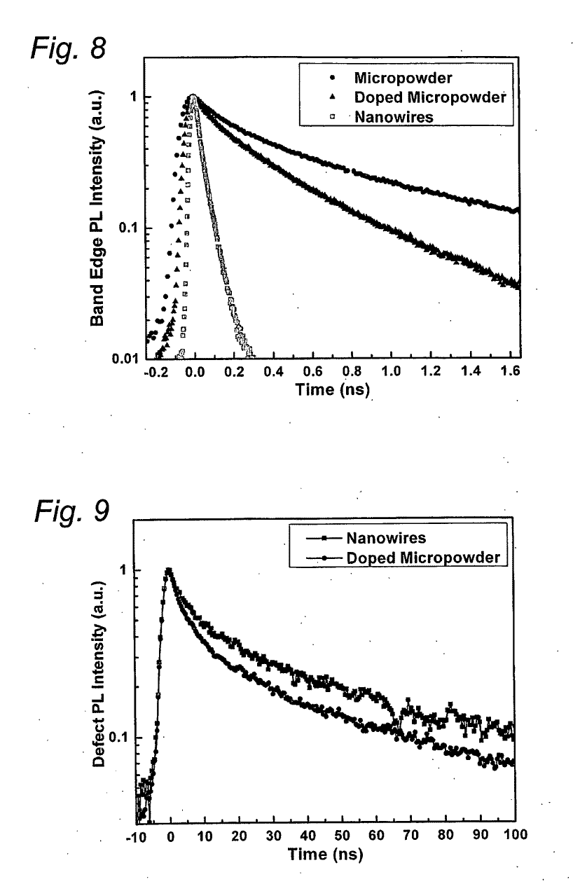

To further explore this theory, the time-resolved photoluminescence (TRPL) decay of the band edge and defect emission from each ZnO sample was measured. If the decay of the band edge emission (Table 1 and FIG. 8) is first considered,³¹ the undoped micropowder exhibits the strongest band edge emission (and the weakest defect emission). Although it has the slowest biexponential decay lifetimes τᵢ(I_{B}(t)=A₁e^{-t/τ}_{₁}+A₂e^{-t/τ}_{₂}, A₁+A₂=1), the low quantum efficiency indicates that nonradiative recombination dominates band edge relaxation. Doping the micropowder with sulfur significantly enhances energy transfer from the band edge to the defect states responsible for visible emission, resulting in reduced band edge emission, faster band edge decay, much brighter visible emission, and dramatically increased quantum efficiency. Clearly the defect-mediated decay channel responsible for visible emission favorably competes with the deleterious nonradiative decay channels. However, when the doped ZnO is formed into nanowires, the band edge emission decay accelerates and the spectrally integrated quantum efficiency drops. Clearly nanostructuring increases nonradiative carrier relaxation, thus undermining the channel favorable for visible emission. It is surmised that as the nanostructure surface-to-volume ratio increases, the nonradiative pathways increasingly compete with the sulfur-induced defects responsible for the bright visible emission.

If the decay of the visible emission itself is next considered, the decay lifetimes were almost independent of emission wavelength across the broad visible emission band for both the doped micropowder and nanowire samples. This suggests a common emission mechanism that is enhanced by the presence of sulfur but is otherwise independent of sample preparation conditions. FIG. 9 compares the spectrally integrated (2.27-2.77 eV) visible emission decay for both samples. The complex, nonexponential decay occurs on a timescale much longer than that of the band edge emission, decreasing to half its initial intensity in 10 ns. The final 10% of this emission decays exponentially with a time constant of ˜50 ns. This may be compared with microsecond lifetimes previously reported in the literature for visible emission in undoped ZnO.^{25,32} The similarity of the two TRPL traces indicates that the nanostructuring process and commensurate increase in nonradiative relaxation pathways has little effect on the decay dynamics of the visible wavelength emitters themselves.

Understanding the mechanism of visible emission in ZnO nanostructures is necessary not only to minimize its effects in cases where band edge ultraviolet emission is important, but also to enhance the mechanism for the purpose of engineering bright emitters and phosphors in the visible spectrum. The sulfur-doped nanowires in accordance with the present invention are clearly a viable broadband light source which can be efficiently and continuously photoexcited by commercially available semiconductor UV emitters. Electrical pumping of the ZnO nanowires is also possible because of their comparatively high electrical conductivity.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

### CITED PUBLICATIONS AND NOTES

The entirety of each of the following cited publications is hereby expressly incorporated hereinto by reference.

(1) Bagnall, D. M.; Chen, Y. F.; Zhu, Z.; Yao, T.; Shen, M. Y.; Goto, T. Appl. Phys. Lett. 1998, 73, 1038-1040.

(2) Tang, Z. K.; Wong, G. K. L.; Yu, P.; Kawasaki, M.; Ohtomo, A.; Koinuma, H.; Segawa, Y. Appl. Phys. Lett. 1998, 72, 3270-3272.

(3) Zu, P.; Tang, Z. K.; Wong, G. K. L.; Kawasaki, M.; Ohtomo, A.; Koinuma, H.; Segawa, Y. Solid State Comm. 1997, 103, 459.

(4) Bagnall, D. M.; Chen, Y. F.; Zhu, Z.; Yao, T.; Koyama, S.; Shen, M. Y.; Goto, T. Appl. Phys. Lett. 1997, 70, 2230-2232.

(5) Reynolds, D. C.; Look, D. C.; Jogai, B. Solid State Comm. 1996, 99, 873.

(6) Reynolds, D. C.; Look, D. C.; Jogai, B.; Litton, C. W.; Cantwell, G.; Harsch, W. C. Phys. Rev. B 1999, 60, 2340.

(7) Xu, S. J.; Liu, W.; Li, M. F. Appl. Phys. Lett. 2002, 81, 2959.

(8) Tsukazaki, A.; Ohtomo, A.; Onuma, T.; Ohtani, M.; Makino, T.; Sumiya, M.; Ohtani, K.; Chichibu, S. F.; Fuke, S.; Segawa, Y.; Ohno, H.; Koinuma, H.; Kawasaki, M. Nature Mater. 2005, 4, 42-46.

(9) Look, D. C.; Claflin, B. Phys. Stat. Sol. B2004, 241, 624-630.

(10) Kim, K.-K.; Kim, H.-S.; Hwang, D.-K.; Lim, J.-H.; Park, S.-J. Appl. Phys. Lett. 2003, 83, 63.

(11) Look, D. C.; Renlund, G. M.; Burgener II, R. H.; Sizelove, J. R. Appl. Phys. Lett. 2004, 85, 5269.

(12) Vaithianathan, V.; Lee, B.-T.; Kim, S. S. Appl. Phys. Lett 2005, 86, 062101.

(13) Ozgur, U.; Teke, A.; Liu, C.; Cho, S. J.; Morkoc, H.; Everitt, H. O. Appl. Phys. Lett. 2004, 84, 3223-3225.

(14) Wang, L.; Giles, N. C. J. Appl. Phys. 2003, 94, 973.

(15) Leiter, F.; Alves, H.; Pfisterer, D.; Romanov, N. G.; Hofmann, D. M.; Meyer, B. K. Physica B 2003, 340-342, 201.

(16) Jung, S. W.; Park, W. I.; Cheong, H. D.; Gyu-Chul, Y.; Hyun, M. J.; Hong, S.; Joo, T. Appl. Phys. Lett. 2002, 80,1924-1926.

(17) Greene, L. E.; Law, M.; Goldberger, J.; Kim, F.; Johnson, J. C.; Zhang, Y.; Saykally, R. J.; Yang, P. Angew. Chem. Int. Ed. 2003, 42, 3031.

(18) Hsu, N. E.; Hung, W. K.; Chen, Y. F. J. Appl. Phys. 2004, 96, 4671.

(19) Liu, X.; Wu, X.; Cao, H.; Chang, R. P. H. J. Appl. Phys. 2004, 95, 3141.

(20) Shalish, I.; Temkin, H.; Narayanamurti, V. Phys. Rev. B 2004, 69, 245401.

(21) Bae, S. Y.; Seo, H. W.; Park, J. J. Phys. Chem. B 2004, 108, 5206-5210.

(22) Geng, B. Y.; Wang, G. Z.; Jiang, Z.; Xie, T.; Sun, S. H.; Meng, G. W.; Zhang, L. D. Appl. Phys. Lett. 2003, 82, 4791.

(23) Shen, G.; Cho, J. H.; Yoo, J. K.; Yi, G. C.; Lee, C. J. J. Phys. Chem. B 2005, 109, 5491-5496.

(24) Vanheusden, K.; Warren, W. L.; Seager, C. H.; Tallant, D. R.; Voigt, J. A.; Gnade, B. E. J. Appl. Phys. 1996, 79, 7983.

(25) van Dijken, A.; Meulenkamp, E. A.; Vanmaekelbergh, D. e. I.; Meijerink, A. J. Phys. Chem. B 2000, 104, 1715.

(26) Li, D.; Leung, Y. H.; Djurisic, A. B.; Liu, Z. T.; Xie, M. H.; Shi, S. L.; Xu, S. J.; Chan, W. K. Appl. Phys. Lett. 2004, 85, 1601-1603.

(27) Djurisic, A. B.; Leung, Y. H.; Choy, W. C. H.; Cheah, K. W.; Chan, W. K. Appl. Phys. Left. 2004, 84, 2635-2637.

(28) Wyszecki, G.; Stiles, W. S. Color science: concepts and methods, quantitative data and formulae; 2nd ed.; Wiley: New York, 1982.

(29) Zhang, Y.; Russo, R. E.; Mao, S. S. Appl. Phys. Lett. 2005, 87, 043106.

(30) Yen, W. M.; Weber, M. J. Inorganic Phosphors: Compositions, Preparation and Optical Properties; CRC Press, 2004; Vol. 20.

(31) In FIG. 3A the apparent rise times differ slightly due to intentional changes in the streak camera's time resolution (110 ps for micropowder, 50 ps for doped micropowder, 30 ps for nanowires). In all cases the rise times are instrument-limited.

(32) Studenikin, S. A.; Cocivera, M. J. Appl. Phys. 2002, 91, 5060.

What is claimed is:

1. A luminescent nanowire capable of emitting bright visible light comprising a doped ZnO having a spectrally integrated ratio of visible to UV light of at least about 200 or greater.

2. The luminescent material of claim 1, wherein the doped ZnO nanowires has a circular or non-circular cross-section.

3. The luminescent material of claim 1, wherein the doped ZnO nanowire is comprised of ZnO which is doped with at least one dopant selected from the group consisting of sulfur, selenium, oxygen, zinc, magnesium, aluminum.

4. A nanowire capable of emitting bright visible light consisting essentially of a sulfur-doped ZnO.

5. A nanowire as in claim 4, having a spectrally integrated ratio of visible to UV light of at least about 1000.

6. A nanowire as in claim 4, having a length of up to about 100 /μm and an average diameter of between about 10 to about 990 nm.

7. A process of fabricating a sulfur-doped ZnO luminescent nanowires comprising forming a source material by mixing ZnS and graphite powder, and heating the source material in the presence of oxygen for a time sufficient to grow sulfur-doped ZnO nanowires.

8. A device for emitting visible light comprising a doped ZnO luminescent nanowires and a UV light source, the doped ZnO nanowires emitting visible light in response to excitation by UV light emitted by the UV light source.

9. The device of claim 8, comprising a transparent or translucent lens covering the UV light source, wherein the doped ZnO luminescent nanowires are present as a coating on a surface of the lens.

10. The device of claim 9, wherein the device comprises multiple UV light sources.

11. The device of claim 10, wherein the lens is a flat panel positioned adjacent the multiple UV light sources.

12. The device of claim 8, wherein the doped ZnO luminescent nanowires have a circular or non-circular cross-section.
